(19) United States
(12) Patent Application Publication
(10) Pub. No.: US 2026/0047147 A1
(43) Pub. Date: Feb. 12, 2026

(54) PLANAR JFET WITH BURIED GATE

(71) Applicant: Microchip Technology Incorporated, Chandler, AZ (US)

(72) Inventors: Shesh Mani Pandey, Gilbert, AZ (US); Bruce Odekirk, Portland, OR (US)

(73) Assignee: Microchip Technology Incorporated, Chandler, AZ (US)

(21) Appl. No.: 19/191,885

(22) Filed: Apr. 28, 2025

Related U.S. Application Data
(60) Provisional application No. 63/682,250, filed on Aug. 12, 2024.

(51) Int. Cl. H10D 30/83; H10D 30/01; H10D 62/17

(52) U.S. Cl. CPC H10D 30/831; H10D 30/0515; H10D 62/343

(57) ABSTRACT

A field-effect transistor with a buried gate, and a method of making the same. A volume of semiconductor material includes first and second ends and left and right sides. A source is located at the first end, a drain is provided, a left first gate structure is located at the left side, and a right first gate structure is located at the right side. A second, buried gate is located between and spaced apart from the source and the drain and the left and right first gate structures so as to be surrounded in first and second dimensions by the semiconductor material. The second gate divides a channel into multiple paths for current to flow between the source and the drain. The second gate includes a projection extending in a third dimension and presenting an exposed surface operable to receive a voltage.

### RELATED APPLICATION

The present U.S. non-provisional patent application is related to and claims priority benefit of an earlier-filed U.S. provisional patent application titled “Planar JFET with Buried Gate,” Ser. No. 63/682,250, filed Aug. 12, 2024. The entire content of the identified earlier-filed application is incorporated by reference as if fully set forth herein.

### FIELD

The present disclosure relates to junction field effect transistors and methods of making them, and more particularly, the various examples described herein concern a planar junction field-effect transistor with a buried gate, and a method of making a planar junction field-effect transistor with a buried gate.

### BACKGROUND

A junction field-effect transistor (JFET) is an active, voltage-controlled semiconductor device, in which varying an electrical voltage between a gate and a source controls an electrical current flowing through a semiconductor channel between a drain and the source. Applications for JFETs include amplifiers, switches, resistors, regulators, oscillators, and choppers. It is generally desirable to improve the performance and reduce the cost of JFETs, but it can be difficult to do so.

This background discussion is intended to provide related information, and is not necessarily prior art.

### SUMMARY

Examples provide a planar JFET with a buried gate, and a method of making a planar JFET with a buried gate. Broadly, a second gate component is embedded, or “buried,” in a volume of semiconductor material of the JFET, so as to be surrounded in at least two dimensions by the semiconductor material, thereby dividing a channel into two or more paths for electrical current to flow between a source component and a drain component. Examples advantageously provide improved performance, including improved gate control and lower electrical resistance to electrical current flow through the channel between the drain and the source, and reduced cost.

In an example, a field-effect transistor may include a volume of semiconductor material, a source, a drain, a channel, a first gate, and a second gate. The volume of semiconductor material may include a first end and a second end. The source may be located at the first end of the volume of semiconductor material, and the channel may be provided by a region of the volume of semiconductor material between the source and drain. The first gate may be located adjacent to the channel. The second gate may be located within the region of the volume of semiconductor material between and spaced apart from the source and drain so as to be surrounded in a first dimension and a second dimension by the volume semiconductor material. The second gate may divide the channel into two or more paths for electrical current to flow between the source and the drain. The second gate may include a projection extending in a third dimension and presenting an exposed surface operable to receive a voltage.

The preceding example may further include any one or more of the following features. The volume of semiconductor material may include a left side and right side. The first gate may include a left first gate structure located at the left side of the volume of semiconductor material and a right first gate structure located at the right side. The second gate may be located within the region of the volume of semiconductor material between and spaced apart from the left first gate structure and the right first gate structure, so that a first path of the channel extends between the left first gate structure and the second gate and a second path of the channel extends between the right first gate structure and the second gate. The source may extend between and abut the left and right first gate structures. The field-effect transistor may have a planar configuration, and the left and right first gate structures may be located at the first end of the volume of semiconductor material. The left and right first gate structures may extend a common length from the first end of the volume of semiconductor material. The gate may have a distal edge spaced closer to the second end of the volume of semiconductor material than the first end of the volume of semiconductor material, and the distal edge of the second gate may be spaced from the first end of the volume of semiconductor material a distance less than the common length of the left and right first gate structures. The first and second gates may be in direct contact with the channel, such that the field-effect transistor may be a junction field-effect transistor. The drain may be located at the second end of the volume of semiconductor material. The second gate may be spaced apart from the source by a distance that is at least sufficient to achieve a breakdown voltage between the second gate and the source. The second gate may extend approximately between two-tenths (0.2) and two (2) micrometers in the first dimension and approximately between two-tenths (0.2) and two (2) micrometers in the second dimension. The second gate may include a single second gate structure located within the region of semiconductor material, or the second gate may include two or more second gate structures located within the region of semiconductor material and spaced apart from each other.

In another example, a method of manufacturing a field-effect transistor with a buried gate may include the following operations. A volume of semiconductor material may be provided including a first end, a second end, a left side, and a right side. A source may be implanted at the first end of the volume of semiconductor material, and a drain may be provided, wherein a channel is provided by a region of the volume of semiconductor material between the source and drain. A first gate may be provided adjacent to the channel. A second gate may be implanted within the region of the volume of semiconductor material between and spaced apart from the source and drain, and between and spaced apart from the left first gate structure and the right first gate structure, so as to be surrounded in a first dimension and a second dimension by the volume semiconductor material. The second gate may divide the channel into a first path for electrical current that extends between the left first gate structure and the second gate and a second path for electrical current that extends between the right first gate structure and the second gate. The step implanting the second gate may include forming a projection of the second gate that extends in a third dimension to present an exposed surface operable to receive a voltage.

The preceding example may further include any one or more of the following features. The step of providing the first gate may include implanting a left first gate structure at the left side of the volume of semiconductor material, and implanting a right first gate structure at the right side of the volume of semiconductor material. The step of implanting the second gate may include positioning the second gate within the region of the volume of semiconductor material between and spaced apart from the left first gate structure and the right first gate structure, so that a first path of the channel may extend between the left first gate structure and the second gate and a second path of the channel may extend between the right first gate structure and the second gate. The step of providing the drain may include forming the drain at the second end of the volume of semiconductor material. The step of implanting the second gate may include the step of spacing the second gate from the source by a distance that is at least sufficient to achieve a breakdown voltage between the second gate and the source. The second gate may be spaced apart from the source by a distance that is at least sufficient to achieve a breakdown voltage between the second gate and the source. The second gate may extend approximately between two-tenths (0.2) and two (2) micrometers in the first dimension and approximately between two-tenths (0.2) and two (2) micrometers in the second dimension. The step of implanting the second gate may include forming the second gate as a single second gate structure located within the region of the volume of semiconductor material, or the step of implanting the second gate may include forming the second gate to include two or more second gate structures located within the region of the volume of semiconductor material and spaced apart from each other.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a cross-sectional elevation view of an example of a planar JFET with a buried gate;

FIG. 2 is a cross-sectional isometric view of the example planar JFET of FIG. 1;

FIG. 3 is a plan view of the example planar JFET of FIG. 1;

FIG. 4 is a cross-sectional elevation view of an example of a planar JFET with a buried gate, wherein the buried gate includes a plurality of structures extending into a channel component of the JFET;

FIG. 5 is a flowchart of operations in an example of a method of manufacturing a planar JFET with a buried gate;

FIG. 6A is a cross-sectional view of the result of an operation in the method of FIG. 5, wherein an N-epitaxial layer is shown on an N+ substrate;

FIG. 6B is a cross-sectional view of the result of an operation in the method of FIG. 5, wherein the addition of N-type material and the implantation of a second gate of P-type material is shown;

FIG. 6C is a cross-sectional view of the result of an operation in the method of FIG. 5, wherein the implantation of a first gate is shown;

FIG. 6D is a cross-sectional view of the result of an operation in the method of FIG. 5, wherein the implantation of a source of N-type material is shown; and

FIG. 6E is a cross-sectional view of the result of an operation in the method of FIG. 5, wherein the addition of electrical terminals are shown.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property. Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation. It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Broadly, examples provide a compact, field-effect transistor (such as a planar junction field effect transistor (JFET)) with a buried gate, and a method of making a compact, field effect transistor with a buried gate. Broadly, a second gate component is embedded, or “buried,” in a volume of semiconductor material of the transistor, so as to be surrounded in at least two dimensions (as seen in cross-sectional elevation view) by the semiconductor material, and thereby divides a channel into two or more paths for electrical current to flow between a source component and a drain component. Examples advantageously provide improved performance, including improved gate control and a lower electric resistance to current flow through the channel between the source and drain when the device is “on,” i.e., examples provide a lower RDS(on) compared to that of a typical transistor, and reduced cost.

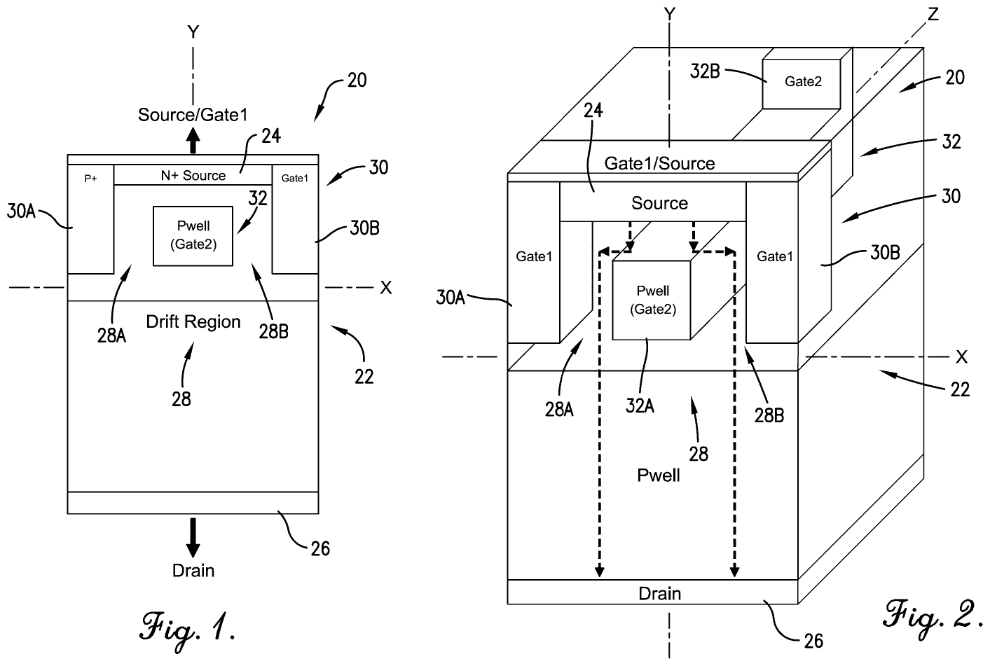

Referring to FIGS. 1-4, an example of a planar JFET 20 with a buried gate may include a volume of semiconductor material 22, a source 24, a drain 26, a channel 28, a first gate 30, and a second gate 32, wherein the second gate 32 may be the buried gate. The relative locations of these components are described below with respect to the X, Y, and Z axes, or dimensions, overlaid onto FIGS. 1-4. It will be understood that these axes, or dimensions, like other terms of relative location or direction, are used to facilitate the present description with reference to the figures and, unless expressly stated, are not meant to be limiting with regard to location, direction, or overall orientation.

The volume of semiconductor material 22 may include a first end, a second end, a first side, and a second side. The volume of semiconductor material 22 may be constructed from or include an N-epitaxial layer and an N-type layer of semiconductor material. The source 24 may be located at or near a first end of the volume of semiconductor material 22 and provide an entrance for majority charge carriers (e.g., electrons for N-channel) into the channel 28. The source 24 may include N+ material. The drain 26 may be spaced apart on the Y axis from the source 24 and located at or near a second end of the volume of semiconductor material 22 and provide an exit for the majority charge carriers from the channel 28. According to some aspects, the drain may alternatively be located at the first end of the volume of semiconductor material. The drain 26 may include N+ material. The channel 28 may be provided by a region of the semiconductor material 22 between the source 24 and the drain 26 and through which the majority charge carriers move, i.e., through which electric current flows. It will be appreciated that the majority charge carriers, which are, in this case, electrons, flow from the source 24 to the drain 26, and the conventional current, Id, flows from the drain 26 to the source 24.

The illustrated example of the first gate 30 may include left and right first gate structures 30A, 30B spaced apart on the X axis and located, respectively along the left side and along the right side of the region of the volume of semiconductor material 22, so as to be positioned adjacent to the channel 28 and, generally, on either side of and abutting the source 24 (with the source 24 extending continuously between the left and right first gate structures 30A, 30B). The left and right first gate structures 30A, 30B may be electrically connected to the same voltage source. The first gate 30 may include P+ material. As noted, the example transistor 20 may have a planar configuration, with the first and second structures 30A, 30B of the first gate 30 being located at the first end of the volume of semiconductor material.

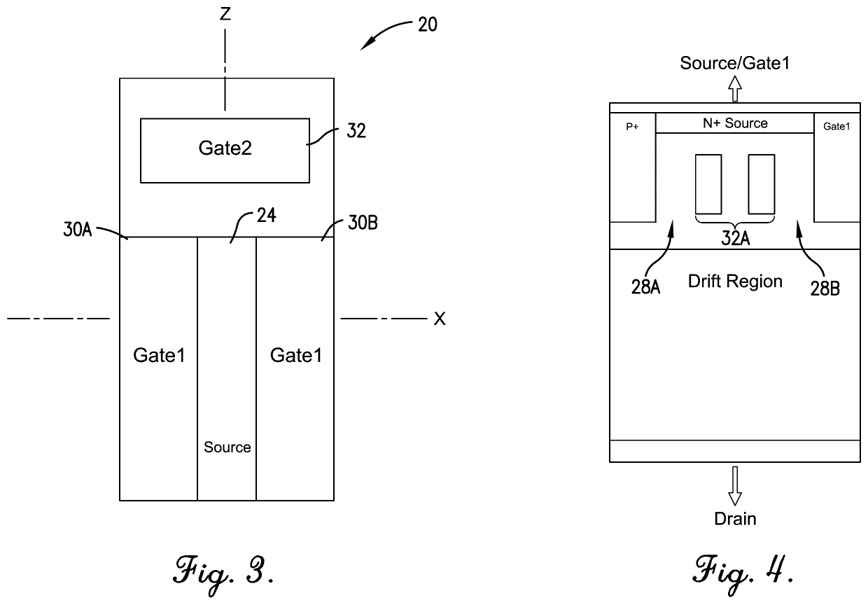

The second gate 32 may be elongated along the Z axis and include first and second portions 32A, 32B. At least a first portion 32A of the second gate 32 may be located within, or “buried” within, the region of the volume of semiconductor material 22 so as to be positioned between and spaced apart from the source 24 and the drain 26. The first portion 32A of the second gate 32 may project along the Z axis to the second portion 32B. The second portion 32B of the second gate 32 may generally extend in the Y axial direction, i.e., at an angle (e.g., ninety (90) degrees, although other angles are with the ambit of the example transistor 20), from an end of the first portion 32A so as to present the exposed surface at the surface of the volume of semiconductor material 22 (see FIG. 3), with the exposed surface being operable to receive a voltage. In examples, an electrical terminal is provided on the exposed surface of the second portion 32B of the second gate 32. Stated another way, the second gate 32 may be surrounded in a first dimension, X, and a second dimension, Y, by the semiconductor material 22, and may extend out of the channel region of the semiconductor material in a third dimension, Z. The second gate 32 then extends along one of the dimensions (the second dimension, Y, in the illustrated embodiment) to present the second portion 32B and the exposed surface for receiving a voltage. In operation, the second gate 32 may function as the primary gate controlling and shielding node.

The first and second gates 30, 32 may be in direct contact with the channel 28, such that the example transistor 20 is a JFET.

The distance between the first portion 32A of the second gate 32 and the source 24 may be sufficient to achieve the breakdown voltage (BVgs) between the second gate 32 and the source 24. The cross-sectional dimensions of the first portion 32A of the second gate 32 may be approximately between two-tenths (0.2) and two (2) micrometers in width and approximately between two-tenths (0.2) and two (2) micrometers in height. There may be one instance of the first portion 32A of the second gate 32 extending into the channel region of the volume of semiconductor material 22, as seen in FIGS. 1-4, or the first portion 32A of the second gate 32 may be divided into two or more instances extending into the channel region of the semiconductor material 22 and adjacent to and spaced apart from each other, as seen in FIG. 4.

In the illustrated example, the first and second sections 30A, 30B of the first gate 30 may be symmetric and may have a common vertical length (extending an equal distance from the first end of the volume of semiconductor material 22), although it is within the ambit of some aspects of the example transistor 20 for the first and second sections 30A, 30B to be asymmetrical in the first and/or second dimensions X, Y. Furthermore, the distal (or lowermost) edge of the second gate 32 may be spaced from the first end of the volume of semiconductor material 22 a distance less than the vertical length of the first and second gate sections 30A, 30B. However, some aspects of the example transistor contemplate a second gate having a lowermost edge spaced equally or further from the first end of the semiconductor material than the distal edge of at least one of the first gate sections.

The source 24 and the first gate 30 may share a first electrical terminal, the drain 26 may be provided with a second electrical terminal, and a third electrical terminal may be provided for the second gate 32, with the terminals serving to facilitate connections to appropriate voltage sources.

In operation, an input voltage, Vds, may be applied across the first and second electrical terminals to cause electron drift/movement from the source 24 to the drain 26, and a control voltage, Vgs, may be applied across the first and third electrical terminals to control the width of the depletion region at the PN junctions where the charge carriers of the P- and N-type materials diffuse into each other, which “depletes” the available concentrations of majority charge carrier in each material, and thereby control the current, Id, from the drain 26 to the source 24. Thus, the source 24, the first gate 30, and the second gate 32 may cooperate under Vgs to control the current, Id, through the channel 28. If Vgs=0 V and Vds>0 V, electrons drift, or move, from the source 24 to the drain 26, resulting in a current, Id, from the drain 26 to the source 24, and increased depletion regions at the PN junctions. If Vds=pinch-off voltage (Vp), then the depletion regions increase in size and grow sufficiently close to each other across the channel 28 that the current, Id, through the channel cannot increase and so is at its maximum, Id=(max drain current (Idss)). In the present examples, the position of the second, buried gate 32 divides the channel 28 into two smaller channels 28A, 28B through which the flow of charge carriers can be controlled.

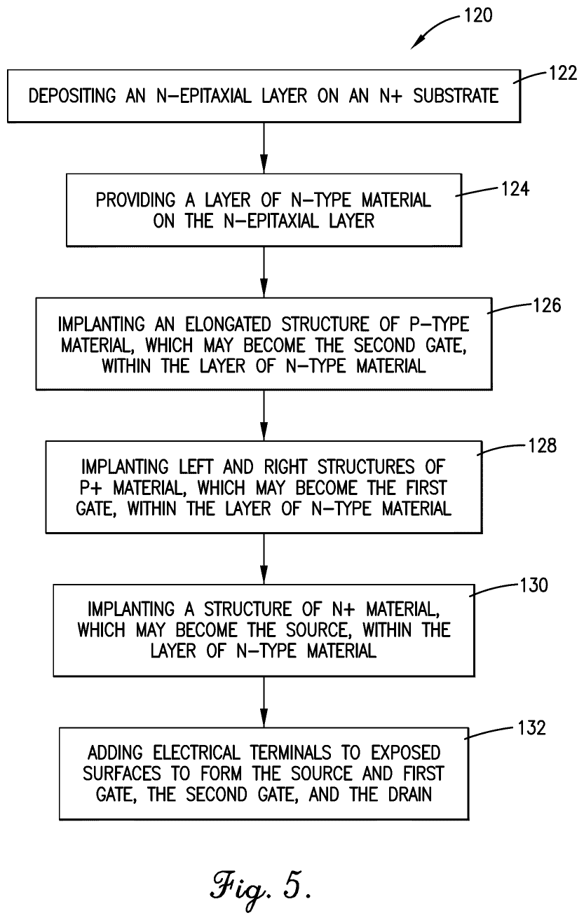

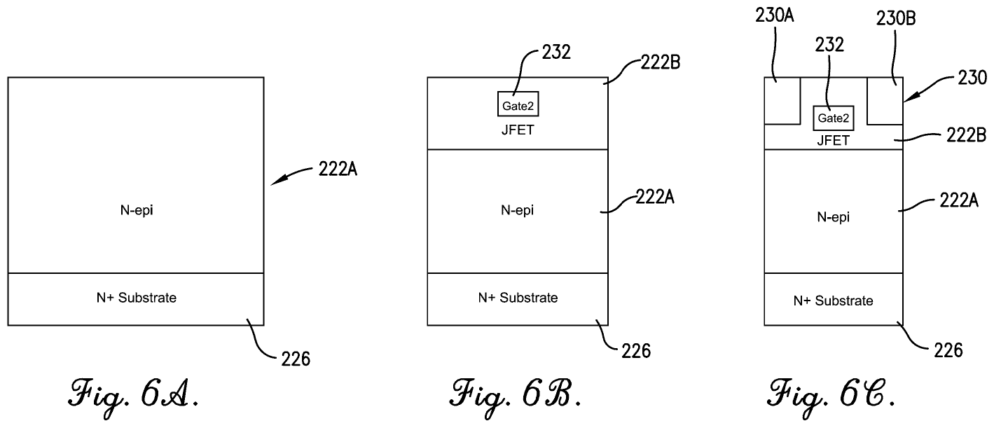

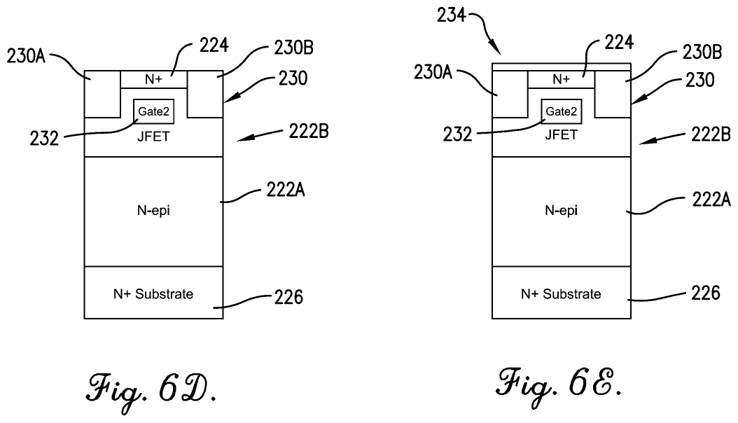

Referring to FIG. 5, an example method 120 of manufacturing the planar JFET 20 with a buried gate of FIG. 1 may include the operations set forth below. Referring additionally to FIGS. 6A-E, example results are shown of the operations of the method 120 and intermediate stages of production of the JFET 20.

An N-epitaxial layer 222A of semiconductor material may be grown or otherwise provided on an N+ substrate 226, as shown in 122 and seen in FIG. 6A, wherein the N+ substrate may become the drain 26. The N+ substrate may be a 4H-SiC material. An additional N-type layer 222B of semiconductor material may be created (through, e.g., implantation) or otherwise provided on the N-epitaxial layer 222A, as shown in 124 and seen in FIG. 6B, wherein the N-epitaxial layer 222A and the N-type layer 222B may, together, form the volume of semiconductor material 22. An elongated structure of P-type material 232, which may become the second gate 32, may be implanted (using, e.g., an ion implanter) or otherwise provided within the N-type layer 222B, as shown in 126 and also seen in FIG. 5B.

The elongated structure of P-type material 232, which may become the second gate 32, may be surrounded in a first dimension, X, and a second dimension, Y, by the N-type layer 222B, and may include the projection 32A extending out of the channel region in a third dimension, Z, as described above. As described above, the first portion, or projection, 32A of the second gate 32 may extend along the Z axis, and the second portion 32B of the second gate 32 may extend in the Y axial direction, i.e., at an angle, from an end of the first portion 32A, so as to present an exposed surface for coupling with an electrical terminal. As described above, there may be one instance of the first portion 32A of the second gate 32 extending into the channel region of the N-type layer 222B, as shown in FIGS. 1-4, or the first portion 32A of the second gate 32 may be divided into two or more instances extending into the channel region of the N-type layer 22B and adjacent to and spaced apart from each other, as shown in FIG. 4. In operation, the second gate 32 may function as the primary gate controlling and shielding node.

Left and right structures of P+ material 232A, 232B, which may become the left and right first gate structures 30A, 30B, may be implanted or otherwise provided on or within the N-type layer 222B, as shown in 128 and seen in FIG. 5C. A structure of N+ material 224, which may become the source 24, may be implanted or otherwise provided on or within the N-type layer 222B, as shown in 130 and seen in FIG. 5D. As described above, the distance between the first portion 32A of the second gate 32 and the source 24 may be sufficient to achieve the breakdown voltage (BVgs) between the second gate 32 and the source 24. The cross-sectional dimensions of the first portion 32A of the second gate 32 may be approximately between two-tenths (0.2) and two (2) micrometers in width and approximately between two-tenths (0.2) and two (2) micrometers in height.

Electrical terminals 234 may be added to exposed surfaces of the source 24 and first gate 30 (with any separate structures of the first gate (e.g., the left and right structures 30A and 30B) sharing a single terminal), the second gate 32, and the drain 26, as shown in 132 and seen in FIG. 5E. Additional processing may be performed as desired.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

For example, it will be appreciated that the sides of the illustrated volume of semiconductor material 22 are defined herein merely as an example, and may in various examples represent only a portion of semiconductor material relative to the illustrated device. In practice, the volume of semiconductor may extend laterally (leftward and rightward when viewing FIG. 1) beyond the bounds illustrated in the drawings to present additional semiconductor material in which additional devices may be provided. (The semiconductor material may similarly extend inwardly or outwardly (relative to the lateral or cross-sectional direction depicted in FIG. 1) to present additional devices in a direction transverse to the lateral direction.) Such additional devices may be FETs (which may be similarly or alternatively constructed to the illustrated transistor 20) or may be entirely different devices providing different operations or functions than the illustrated transistor 20. In other words, in practice, the illustrated transistor 20 may be just one of numerous devices spaced laterally and transversely within a single, integrally formed array, such as a wafer (not shown).

Furthermore, although described herein with regard or in relation to one or more particular kinds of electronic devices (e.g., junction field-effect transistor, metal oxide semiconductor field-effect transistor), the technology may be more broadly applicable to one or more other kinds of electronic devices as well. Further, one with ordinary skill in the art will recognize that the technology described herein may, when applicable, be implemented in enhancement mode or depletion mode. Additionally, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum dioxide, hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations for contact implants may be approximately between 10\hat{ }18 and 1×\hat{ }22; doping concentrations for channel and threshold forming implants may be approximately between 10\hat{ }16 and 10\hat{ }17; doping concentrations for shielding implants may be approximately between 10\hat{ }17 and 10\hat{ }19; and doping concentrations for conductivity improvement implants (e.g., N-doping in the junction field-effect transistor neck region of a metal oxide semiconductor field-effect transistor) may be approximately between 10\hat{ }16 and 10\hat{ }17. Relatedly, a structure or region may contain two or more different doping doses. For example, one with ordinary skill in the art will recognize that some P-wells may contain a lower dose P-well portion and a higher dose unclamped inductive switching portion.

1. A field-effect transistor comprising:
a volume of semiconductor material including a first end and a second end;
a source located at the first end of the volume of semiconductor material;
a drain;
a channel provided by a region of the volume of semiconductor material between the source and drain;
a first gate located adjacent to the channel; and
a second gate located within the region of the volume of semiconductor material between and spaced apart from the source and drain so as to be surrounded in a first dimension and a second dimension by the volume semiconductor material, the second gate dividing the channel into two or more paths for electrical current to flow between the source and the drain, and the second gate including a projection extending in a third dimension to present an exposed surface operable to receive a voltage.

2. The field-effect transistor of claim 1, wherein the volume of semiconductor material includes a left side and right side, the first gate includes a left first gate structure located at the left side of the volume of semiconductor material and a right first gate structure located at the right side of the volume of semiconductor material, and the second gate is located within the region of the volume of semiconductor material between and spaced apart from the source and drain and between and spaced apart from the left first gate structure and the right first gate structure, so that a first path of the channel extends between the left first gate structure and the second gate and a second path of the channel extends between the right first gate structure and the second gate.

3. The field-effect transistor of claim 2, wherein the source extends between and abuts the left and right first gate structures.

4. The field-effect transistor of claim 2, wherein the field-effect transistor has a planar configuration, and the left and right first gate structures are located at the first end of the volume of semiconductor material.

5. The field-effect transistor of claim 4, wherein the left and right first gate structures extend a common length from the first end of the volume of semiconductor material.

6. The field-effect transistor of claim 5, wherein the second gate has a distal edge spaced closer to the second end of the volume of semiconductor material than the first end of the volume of semiconductor material, the distal edge of the second gate being spaced from the first end of the volume of semiconductor material a distance less than the common length of the left and right first gate structures.

7. The field-effect transistor of claim 1, wherein the first and second gates are in direct contact with the channel, such that the field-effect transistor is a junction field-effect transistor.

8. The field-effect transistor of claim 1, wherein the drain is located at the second end of the volume of semiconductor material.

9. The field-effect transistor of claim 1, wherein the second gate is spaced apart from the source by a distance that is at least sufficient to achieve a breakdown voltage between the second gate and the source.

10. The field-effect transistor of claim 1, wherein the second gate extends between two-tenths (0.2) and two (2) micrometers in the first dimension and between two-tenths (0.2) and two (2) micrometers in the second dimension.

11. The field-effect transistor of claim 1, wherein the second gate includes a single second gate structure located within the region of the volume of semiconductor material.

12. The field-effect transistor of claim 1, wherein the second gate includes two or more second gate structures located within the region of the volume of semiconductor material and spaced apart from each other.

13. A method of manufacturing a field-effect transistor with a buried gate, the method comprising:
providing a volume of semiconductor material including a first end, a second end, a left side, and a right side;
implanting a source at the first end of the volume of semiconductor material;
providing a drain,
wherein a channel is provided by a region of the volume of semiconductor material between the source and drain;
providing a first gate adjacent to the channel;
implanting a second gate within the region of the volume of semiconductor material between and spaced apart from the source and drain so as to be surrounded in a first dimension and a second dimension by the volume semiconductor material, the second gate dividing the channel into two or more paths for electrical current to flow between the source and the drain,
the step of implanting the second gate including forming a projection of the second gate that extends in a third dimension to present an exposed surface operable to receive a voltage.

14. The method of claim 13, wherein the step of providing the drain includes forming the drain at the second end of the volume of semiconductor material.

15. The method of claim 13,
the step of providing the first gate includes implanting a left first gate structure at the left side of the volume of semiconductor material, and implanting a right first gate structure at the right side of the volume of semiconductor material,
the step of implanting the second gate includes positioning the second gate within the region of the volume of semiconductor material between and spaced apart from the left first gate structure and the right first gate structure, so that a first path of the channel extends between the left first gate structure and the second gate and a second path of the channel extends between the right first gate structure and the second gate.

16. The method of claim 13, wherein the step of implanting the second gate includes the step of spacing the second gate from the source by a distance that is at least sufficient to achieve a breakdown voltage between the second gate and the source.

17. The method of claim 13, wherein the second gate extends between two-tenths (0.2) and two (2) micrometers in the first dimension and between two-tenths (0.2) and two (2) micrometers in the second dimension.

18. The method of claim 13, wherein the step of implanting the second gate includes forming the second gate as a single second gate structure located within the region of the volume of semiconductor material.

19. The method of claim 13, wherein the step of implanting the second gate includes forming the second gate to include two or more second gate structures located within the region of the volume of semiconductor material and spaced apart from each other.
